(19) United States
(12) Patent Application Publication
(10) Pub. No.: US 2026/0198036 A1
(43) Pub. Date: Jul. 9, 2026

(54) MONOLITHICALLY INTEGRATED GALLIUM NITRIDE CASCODE

(71) Applicant: National Tsing Hua University, Hsinchu City (TW)

(72) Inventor: Meng-Chyi WU, Hsinchu City (TW)

(21) Appl. No.: 19/196,794

(22) Filed: May 2, 2025

(30) Foreign Application Priority Data
Jan. 3, 2025 (TW) 114100332

(51) Int. Cl. H10D 30/47; H10D 30/01; H10D 62/10; H10D 62/824; H10D 62/832; H10D 64/00; H10D 64/62; H10D 64/66; H10D 84/82; H10D 86/00

(52) U.S. Cl. CPC H10D 30/475; H10D 62/102; H10D 62/824; H10D 62/8325; H10D 64/111; H10D 64/62; H10D 64/667; H10D 84/82; H10D 86/00; H10D 30/015

(57) ABSTRACT

A monolithically integrated GaN cascode includes a substrate, a buffer layer formed on the substrate, a GaN channel layer formed on the buffer layer, an AlGaN layer formed on the GaN channel layer, a source electrode unit formed on the AlGaN layer, a drain electrode unit formed on the AlGaN layer, an E-gate electrode unit formed between the source electrode unit and the drain electrode unit, and including a P-type doped GaN layer, and an E-gate electrode that is disposed on the P-type doped GaN layer, and a D-gate electrode formed between the source electrode unit and the drain electrode unit, electrically connected to the source electrode unit, and including a D-gate electrode. The P-type doped GaN layer is disposed between the E-gate electrode and the AlGaN layer, and is not disposed between D-gate electrode and the AlGaN layer.

### CROSS-REFERENCE TO RELATED APPLICATION

This application claims priority to Taiwanese Invention Patent Application No. 114100332, filed on Jan. 3, 2025, the entire disclosure of which is incorporated by reference herein.

### FIELD

The disclosure relates to a GaN cascode, and more particularly to a monolithically integrated GaN cascode.

### BACKGROUND

Gallium nitride (GaN) high electron mobility transistors (HEMT) are currently widely employed in integrated circuits. Because the two dimensional electron gas (2DEG) in GaN naturally forms conductive channels, a GaN field effect transistors (GaN FET), for example, is naturally “on” where it is conducting electricity even with zero voltage applied to its gate, and will have characteristics such as high electron mobility. This is in contrast to a naturally “off” GaN FET which does not conduct current unless actively turned on by a positive gate voltage; this is considered the preferred behavior for most power electronics applications due to its safety and simplified gate driver design.

A currently used technology in GaN FET is cascoding. For example, a naturally “on” or depletion mode (D-mode) GaN HEMT may be serially connected to a naturally “off” or enhancement mode (E-mode) silicon metal oxide semiconductor field effect transistor (Si MOSFET), where the Si MOSFET is the driver and the GaN HEMT is the load to achieve characteristics equivalent to a GaN FET. However, a D-mode GaN HEMT serially connected to an E-mode Si MOSFET has many drawbacks. For example, using a Si MOSFET is restrictive when operating at high temperatures, increases structural size which makes packaging more complex, and may increase parasitic capacitance. It should be noted that an increase in parasitic capacitance may negatively affect the switching characteristics of the FET.

Another conventional way of achieving a naturally “off” GaN FET via integrated casocoding of GaN FETs is described below. Referring to FIG. 1, a conventional integrated GaN cascoded FET includes a silicon substrate P1, a buffer layer P2, a GaN channel layer P3, an AlGaN barrier layer P4, a GaN cover layer P5, a dielectric layer P6, a source electrode P7, a drain electrode P8, a E-gate electrode P9, a D-gate electrode P10, two passivation layers P11, and a source field plate P12. The GaN cover layer P5 and the AlGaN barrier layer P4 are located below the E-gate electrode P9 due to the formation of a fluoride ion implantation area in the conventional integrated GaN cascoded FET below the E-gate electrode P9. However, the fluoride ion implantation area changes the junction characteristics between the AlGaN barrier layer P4 and the GaN channel layer P3, blocks the formation of 2DEG, and causes the E-gate electrode P9 to have naturally “off” characteristics. Furthermore, since an area below the D-gate electrode P10 does not undergo fluoride ion implantation, it will continue to have naturally “on” gate characteristics. Therefore because the conventional integrated GaN cascoded FET undergoes fluoride ion implantation, high energy ions will bombard and damage the crystal structure, thereby causing the conventional integrated GaN cascode to have worse electrical characteristics.

### SUMMARY

Therefore, an object of the disclosure is to provide a monolithically integrated GaN cascode that can alleviate at least one of the drawbacks of the prior art.

According to the disclosure, the monolithically integrated GaN cascode includes a substrate, a buffer layer, a GaN channel layer, an AlGaN layer, a source electrode unit, a drain electrode unit, an E-gate electrode unit, and a D-gate electrode unit. The buffer layer is formed on the substrate. The GaN channel layer is formed on the buffer layer. The AlGaN layer is formed on the GaN channel layer. The source electrode unit is formed on the AlGaN layer. The drain electrode unit is formed on the AlGaN layer. The E-gate electrode unit is formed between the source electrode unit and the drain electrode unit on the AlGaN layer, and includes a P-type doped GaN layer, and an E-gate electrode that is disposed on the P-type GaN layer. The D-gate electrode unit is formed between the source electrode unit and the drain electrode unit on the AlGaN layer, is electrically connected to the source electrode unit, and includes a D-gate electrode on the AlGaN layer. The P-type doped GaN layer is disposed between the E-gate electrode and the AlGaN layer, and is not disposed between the D-gate electrode and the AlGaN layer.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is schematic cross-sectional view illustrating a conventional integrated GaN cascoded FET.

FIG. 2 is a schematic view illustrating a circuit diagram of the embodiment of the present disclosure.

FIG. 3 is a schematic cross-sectional view illustrating an embodiment of a monolithically integrated GaN cascode according to the present disclosure.

FIG. 4 is a schematic cross-sectional view illustrating a modified version of the embodiment.

FIG. 5 is an energy band diagram of a D-gate electrode unit of the monolithically integrated GaN cascode without a dielectric layer.

FIG. 6 is an energy band diagram of an E-gate electrode unit of the monolithically integrated GaN cascode.

FIG. 7 is a schematic cross-sectional view illustrating another modified version of the embodiment of the present disclosure.

FIG. 8 shows plots of transistor characteristics and intrinsic transconductance comparing embodiment samples respectively using a silicon carbide substrate and a silicon substrate.

FIG. 9 is an output characteristics diagram comparing the embodiment samples using a silicon carbide substrate and a silicon substrate.

FIG. 10 is a breakdown voltage diagram comparing the embodiment samples using a silicon carbide substrate and a silicon substrate.

FIG. 11 shows output characteristics at varying temperatures which compares the embodiment samples using a silicon carbide substrate and a silicon substrate.

FIG. 12 is a wave diagram showing results from double pulse testing the embodiment sample using a silicon carbide substrate.

FIG. 13 is a wave diagram showing results from double pulse testing the embodiment sample using a silicon substrate.

FIGS. 14 to 21 are schematic views illustrating processing steps in a method of making the embodiment of a monolithically integrated GaN cascode according to the present disclosure.

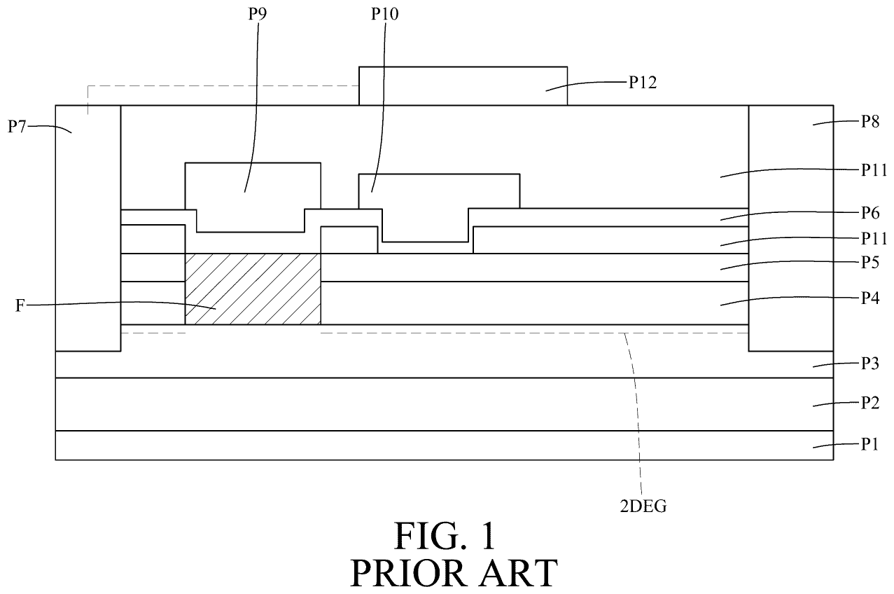

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

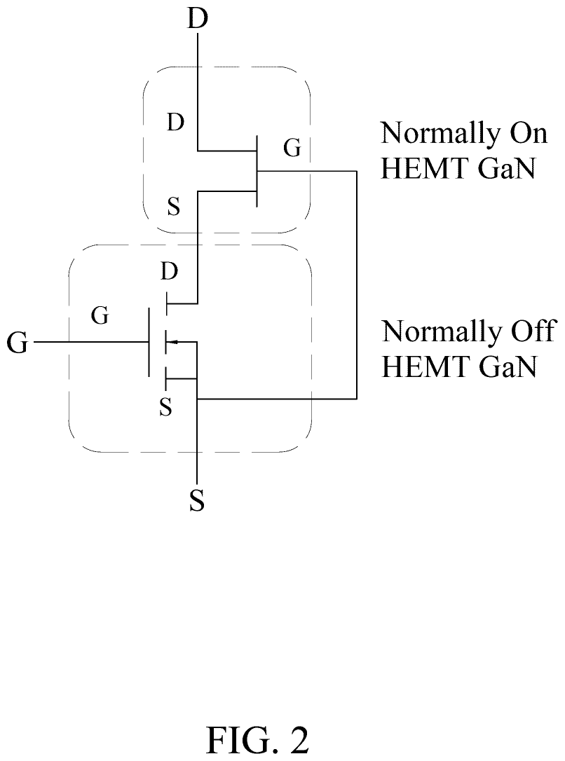

Referring to FIG. 2, a schematic diagram of a monolithically integrated gallium nitride (GaN) cascode according to the present disclosure shows that the monolithically integrated gallium nitride cascode is basically composed of a naturally “on” GaN high electron mobility transistor (HEMT) serially connected with a naturally “off” GaN HEMT.

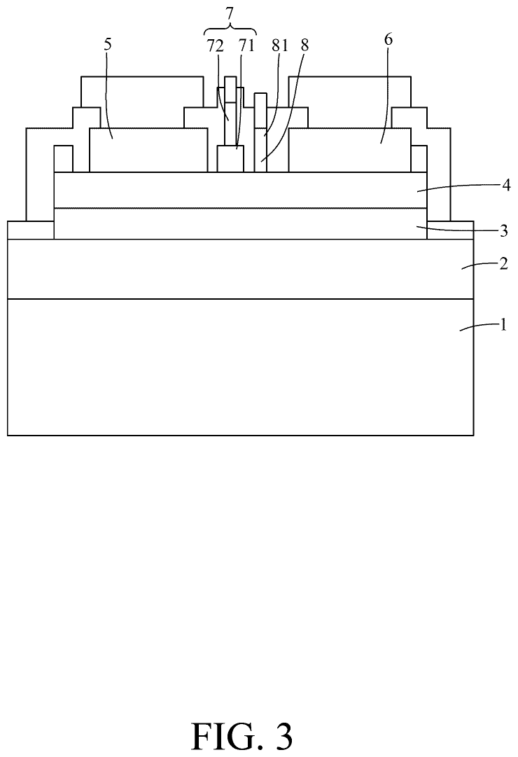

Referring to FIG. 3, an embodiment of the monolithically integrated GaN cascode includes a substrate 1, a buffer layer 2, a GaN channel layer 3, an AlGaN layer 4, a source electrode unit 5, a drain electrode unit 6, an E-gate electrode unit 7, and a D-gate electrode unit 8. The buffer layer 2 is formed on the substrate 1. The GaN channel layer 3 is formed on the buffer layer 2. The AlGaN layer 4 is formed on the GaN channel layer 3. The source electrode unit 5 is formed on the AlGaN layer 4. The drain electrode unit 6 is formed on the AlGaN layer 4. The E-gate-electrode unit 7 is formed between the source electrode unit 5 and the drain electrode unit 8 on the AlGaN layer 4, and includes a P-type doped GaN layer 71, and an E-gate electrode 72 that is disposed on the P-type doped GaN layer 71. The D-gate electrode unit 8 is formed between the source electrode unit 5 and the drain electrode unit 6 on the AlGaN layer 4, is electrically connected to the source electrode unit 5, and includes a D-gate electrode 81 disposed on the AlGaN layer 4. It is noted that the P-type doped GaN layer 71 is disposed between the E-gate electrode 72 and the AlGaN layer 4, and is not disposed between the D-gate electrode 8 and the AlGaN layer 4.

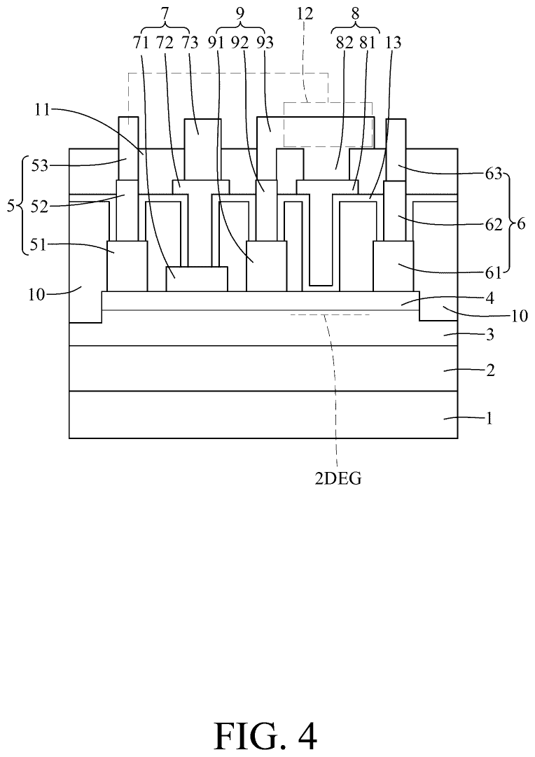

Referring to FIG. 4, in one modified version of the embodiment, aside from the substrate 1, the buffer layer 2, the GaN channel 3, the aluminum gallium nitride (AlGaN) layer 4, the source electrode unit 5, the drain electrode unit 6, the E-gate electrode unit 7, the D-gate electrode unit 8, and the insulating layer 10, the monolithically integrated GaN cascode includes a node electrode unit 9, a protection layer 11, a source field plate 12, and a dielectric layer 13.

In this modified version of the embodiment, the substrate 1, may be, including but not limited to, a silicon substrate, a silicon carbide substrate, a sapphire substrate or an insulating silicon substrate. The buffer layer 2 is formed on the substrate 1. The GaN channel layer 3 is formed on the buffer layer 2. The AlGaN layer 4 is formed on the GaN channel layer 3.

The source electrode unit 5 is formed on the AlGaN layer 4, and includes a source electrode 51, a source electrode pillar 52, and a source electrode pad 53 that are sequentially formed on top of each other on the AlGaN layer 4. The drain electrode unit 6 is formed on the AlGaN layer 4, and includes a drain electrode 61, a drain electrode pillar 62, and a drain electrode pad 63 that are sequentially formed on top of each other on the AlGaN layer 4. Each of the source electrode 51 and the drain electrode 61 may be formed from a Ti/Al/Ti/Au metal layer. Each of the source electrode pillar 52, the drain electrode pillar 62, the source electrode pad 53, the drain electrode pad 63 may be formed from a Ni/Au metal layer.

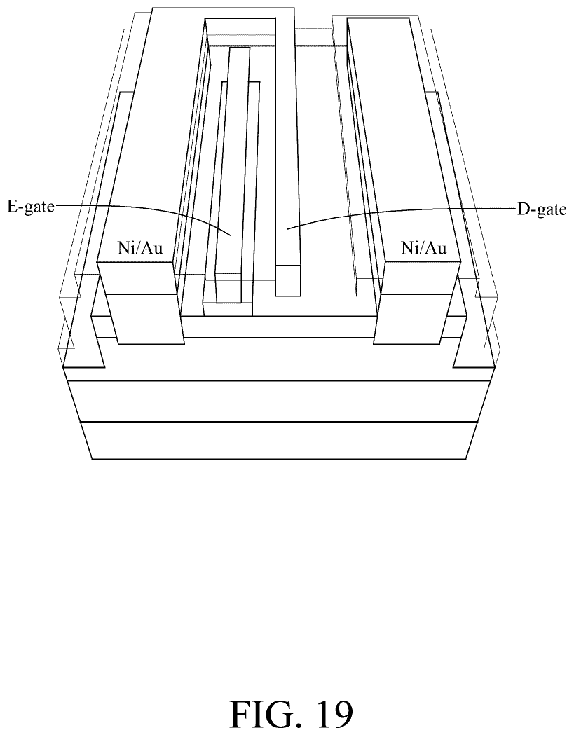

The E-gate electrode unit 7 is formed between the source electrode unit 5 and the drain electrode unit 6 on the AlGaN layer 4. The E-gate electrode unit 7 includes a P-type doped GaN layer 71, and an E-gate electrode 72 that is disposed on the P-type GaN layer 71, and a E-gate electrode pad 73 that is disposed on the E-gate electrode 72. It is noted that in this embodiment, the P-type doped GaN layer 71 may be doped with a P-type dopant such as Mg at a concentration of 2×10¹⁷ cm⁻³. The D-gate electrode unit 8 is formed between the source electrode unit 5 and the drain electrode unit 6 on the AlGaN layer 4. The D-gate electrode unit 8 includes a D-gate electrode 81 and a D-gate electrode pad 82 disposed on the D-gate electrode 81. The D-gate electrode unit 8 is electrically connected to the source electrode unit 5. More specifically, the D-gate electrode pad 82 of the D-gate electrode unit 8 is electrically connected to the source electrode pad 53 of the source electrode unit 5(see FIG. 19). The E-gate electrode 72, the D-gate electrode 81, the E-gate electrode pad 73, and the D-gate electrode pad 82 may be, but not limited to, an Ni/Au metal layer.

The node electrode unit 9 is disposed between the E-gate electrode unit 7 and the D-gate electrode unit 8 on the AlGaN layer 4. The node electrode unit 9 includes a node electrode 91, a node electrode pillar 92 disposed on the node electrode 91, and a node electrode pad 93 disposed on the node electrode pillar 92. The node electrode unit 9 is electrically connected to the D-gate electrode unit 8. More specifically, the node electrode pad 93 of the node electrode unit 9 is electrically connected to the D-gate electrode pad 82 of the D-gate electrode unit 8. The node electrode unit 8 acts as a common electrode for the naturally “on” GaN HEMT and the naturally “off” HEMT, and is the node connecting the two.

The insulating layer 10 is formed on the AlGaN layer 3 to surround source electrode unit 5, the E-gate electrode unit 7, the node electrode unit 9, the D-gate electrode unit 8, and the drain electrode unit 6, and acts as an electrical insulator. The protections layer 11 partially covers the source electrode unit 5, the drain electrode unit 6, the E-gate electrode unit 7, the D-gate electrode unit 8, the node electrode unit 9, and is located above the insulating layer 10. The protection layer 11 acts to protect the monolithically integrated GaN cascode from external moisture. The insulating layer 10 and the protection layer 11 may be made of, but not limited to, (SiNₓ).

The source field plate 12 is disposed in a spaced apart manner above a side of the D-gate electrode unit 8 that is away from the substrate 1, and electrically connected to the source electrode 5. The source field plate 12 allows a bias voltage applied to the D-gate drain electrode 8 to more effectively disperse hot electrons in the AlGaN layer 4 which prevents the hot electrons from repelling electrons in the GaN channel layer 3.

In this modified version of the embodiment, the dielectric layer 13 is disposed between the insulating layer 10 and the protection layer 11. The dielectric layer 13 is disposed between and in contact with the D-gate electrode 81 and the AlGaN layer 4. Additionally, the dielectric layer 13 surrounds the D-gate electrode 81, the drain electrode 61 of the drain electrode unit 6, the node electrode unit 9, the E-gate electrode 72, and the source electrode 51 of the source electrode unit 5.

In a variation of this modified version, the dielectric layer 13 is not disposed between the P-type doped GaN layer 71 and the E-gate electrode 72 of the E-gate electrode unit 7 so that the E-gate electrode 72 directly contacts the P-type doped GaN layer 71 and forms a metal semiconductor (MS) structure. The dielectric layer 13 is disposed between the D-gate electrode 81 of the D-gate electrode unit 8 and the AlGaN layer 4 and forms a metal insulator semiconductor (MIS) structure.

In another variation of the modified version of the embodiment, the dielectric layer 13 is disposed between the E-gate electrode 72 and the P-type doped GaN layer 71 of the E-gate electrode unit 7 to form the MIS structure. However, the dielectric layer 13 is not disposed between the D-gate electrode 81 and the AlGaN layer 4 (not shown in the Figures) and the D-gate electrode 81 of the D-gate electrode unit 8 directly contacts the AlGaN layer 4 to form a MS structure.

In still another variation of the modified version, the dielectric layer 13 is not disposed between the E-gate electrode 72 and the P-type doped GaN layer 71 of the E-gate electrode unit 7 nor between the D-gate electrode 81 of the D-gate electrode unit 8 and the AlGaN layer 4 (not shown in the Figures). In this case, both the E-gate electrode unit 7 and the D-gate electrode unit 8 include MS structures.

In still another variation of the modified version, the dielectric layer 13 may be disposed both between the P-type doped GaN layer 71 and the E-gate electrode of the E-gate electrode unit 7, and between the D-gate electrode 81 of the D-gate electrode unit 8 and the AlGaN layer 4. Therefore, in this case both the E-gate electrode unit 7 and the D-gate electrode unit 8 include MIS structures.

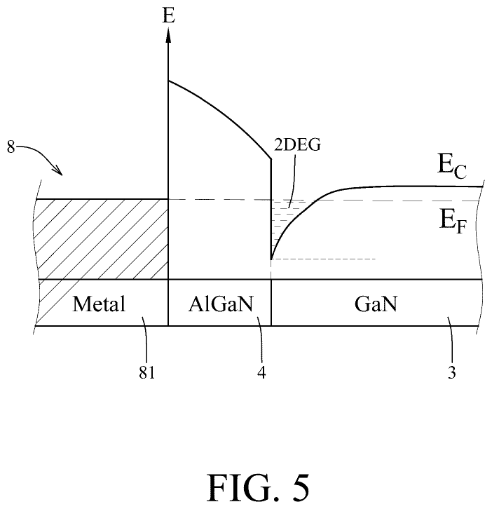

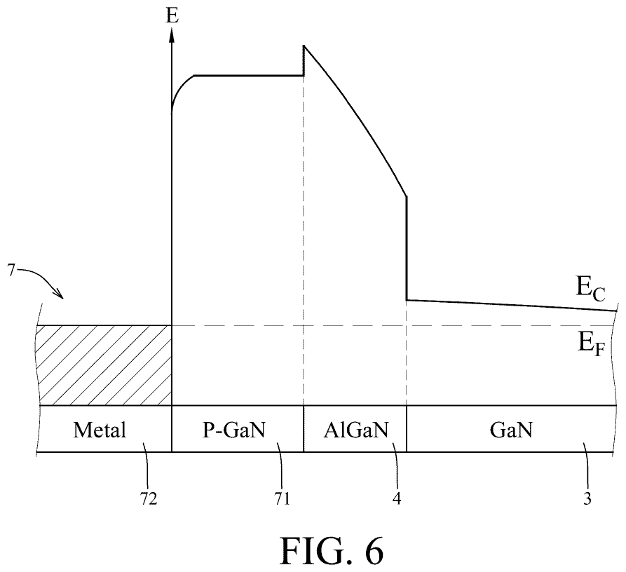

FIG. 5 shows an energy band diagram of the D-gate electrode unit 8 without the dielectric layer 13. Referring to FIG. 5, the D-gate electrode unit 8 acts like a naturally “on” gate electrode, due to energy junction band characteristics between the AlGaN layer 4 and the GaN channel layer 3 two dimensional electron gas (2DEG) will naturally be formed in the GaN channel layer 3 and therefore the GaN channel layer 3 has negative threshold voltage. Referring to FIG. 6, the E-gate electrode unit 7 is a naturally “off” gate electrode. In this case, the formation of the 2DEG is blocked by disposing the P-type doped GaN layer 71 between the AlGaN layer 4 and the E-gate electrode 72 which will change the energy junction band characteristics between the AlGaN layer 4 and the GaN channel layer 3, and cause the GaN channel layer 3 to have a positive threshold voltage.

Therefore, when the naturally “on” GaN HEMT and the naturally “off” GaN HEMT are cascoded together a naturally “off” monolithically integrated GaN cascode is formed. Furthermore, because the formation of a fluoride ion implantation region may be omitted in the embodiment, the crystal structure of the monolithically integrated GaN cascode may be preserved; formation of the implantation region in the prior art would involve bombardment by high energy ions which may destroy the crystal structure. Therefore the monolithically integrated GaN cascode of the present disclosure has more favorable electrical characteristics in comparison to the prior art.

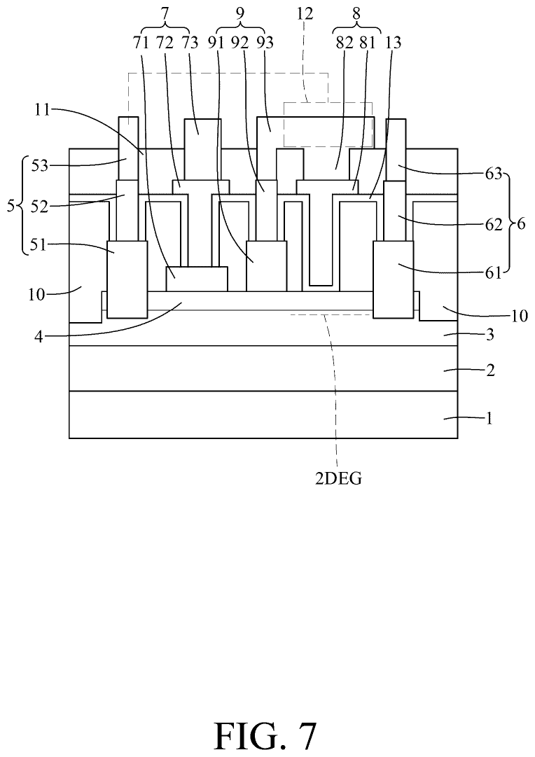

Referring to FIG. 7, another modified version of the embodiment of the monolithically integrated GaN cascode according to the present disclosure is generally similar to the modified version shown in FIG. 6; however, the source electrode unit 5 in FIG. 7 extends into the GaN channel Layer 3 and the AlGaN layer 4 which are recessed, and the drain electrode unit 6 extends into the GaN channel layer 3 and the AlGaN layer 4 which are recessed. Therefore the source electrode 51 and the drain electrode 61 are in direct contact with the GaN channel layer 3 which may reduce electrical resistance from the series connection of the cascode.

As described hereinbefore, the substrate 1 may be a silicon substrate, a silicon carbine substrate, a sapphire substrate, or an insulating silicon substrate. It should be noted that the selection of a silicon carbide substrate offers advantages such as a relatively higher hardness, good thermal conductivity and pressure tolerance, and good switching characteristics.

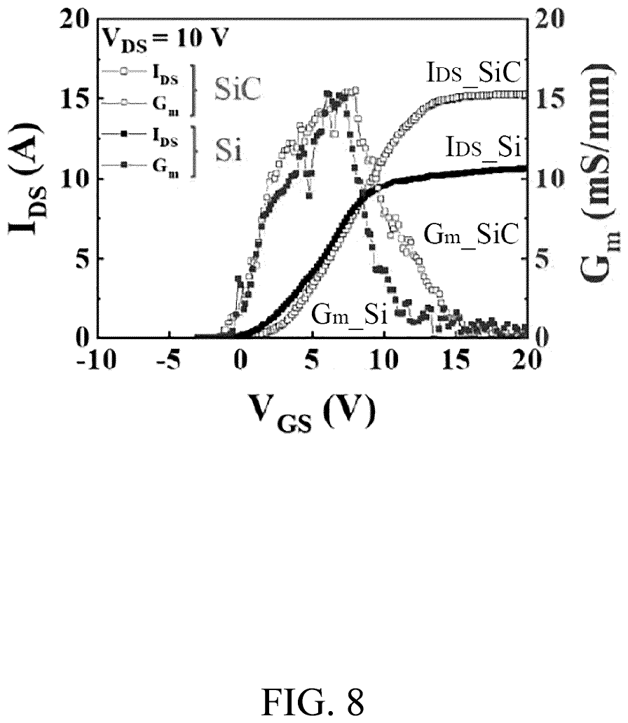

FIG. 8 shows transistor characteristics and extrinsic transconductance values comparing an embodiment sample using a silicon carbide substrate with another embodiment sample using a silicon substrate. It is shown that the embodiment sample with the silicon carbide substrate has a threshold voltage of 0.7 V, a drain current of 15.2 A, a maximum extrinsic transconductance of 15.5 mS/mm, and a Iₒₙ/I_{off} ratio of 5.4×10⁶. The embodiment sample with the silicon substrate has a threshold voltage of 0.5 V, a drain current of 10.6 A, a maximum extrinsic transconductance of 15.3 mS/mm, and a Iₒₙ/I_{off} ratio of 2.7×10⁶.

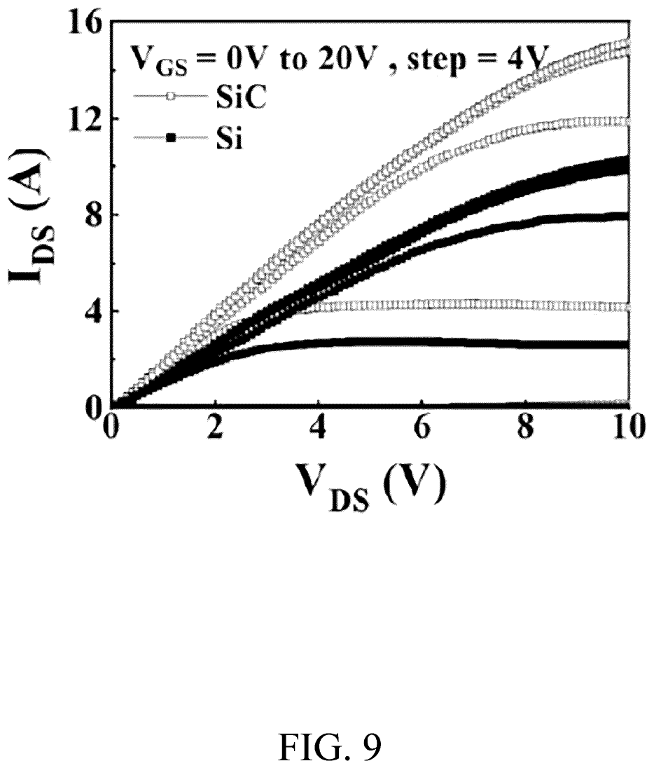

FIG. 9 shows a comparison of output characteristics of the embodiment samples using a silicon carbide substrate and a silicon substrate. It is noted that the embodiment sample with the silicon carbide substrate has a drain-source on-resistance (RDS(on)) of 52 ′Ω-mm, and the embodiment sample with the silicon substrate has an RDS(on) of 65 ′Ω-mm.

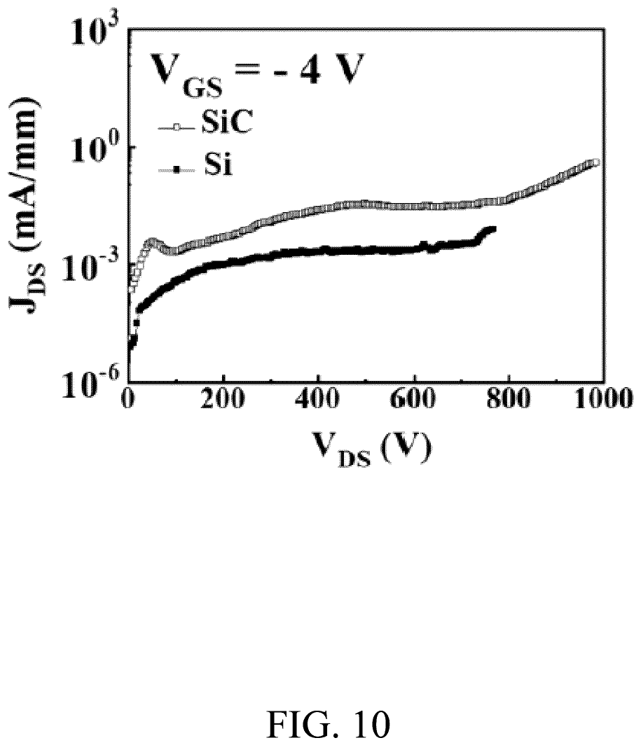

FIG. 10 shows a breakdown voltage comparison of the embodiment sample using a silicon carbide substrate with the embodiment sample using a silicon substrate. It is noted from FIG. 10 that under conditions of a leakage current of 1 mA/mm, the embodiment sample using the silicon carbide substrate has a breakdown voltage of 984 V, and the embodiment sample using the silicon substrate has a breakdown voltage of 783 V.

From FIGS. 8, 9 and 10, it may be observed that in comparison to the embodiment sample using a silicon substrate, the embodiment using a silicon carbide substrate may have higher drain current, higher current switching characteristics, higher breakdown voltage, and therefore have better switching characteristics and higher pressure tolerance.

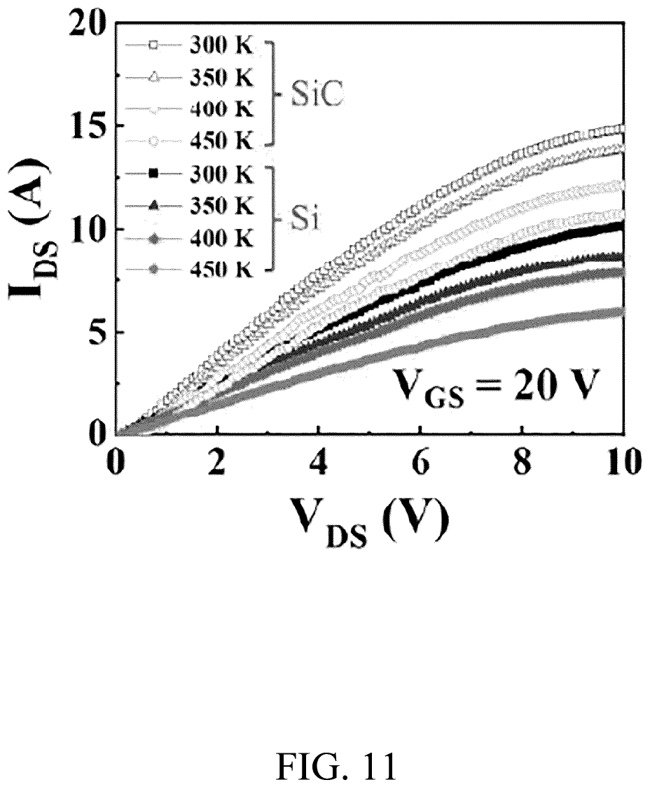

FIG. 11 is a comparison showing output characteristics at different temperatures of the embodiment samples respectively using the silicon substrate and the silicon carbide substrate. From FIG. 11 it is observable that the embodiment sample using the silicon carbide substrate has output current attenuation rate of 0%, 6.5%, 18.2 %, 27.8% respectively at temperatures of 300 K, 350 K, 400 K, 450 K, and normalized RDS(on) of 1, 1.21, 1.37, 1.71, respectively.

From FIG. 11 it is apparent that in comparison to the embodiment sample using the silicon substrate, the embodiment sample using the silicon carbide substrate has improved thermal conductivity and improved heat dissipation characteristics. Furthermore, it is observable from FIG. 11 that under high environmental temperature current attenuation rate is decreased for the embodiment sample using the silicon carbide substrate; therefore, the embodiment sample with silicon carbide substrate is more heat resistant.

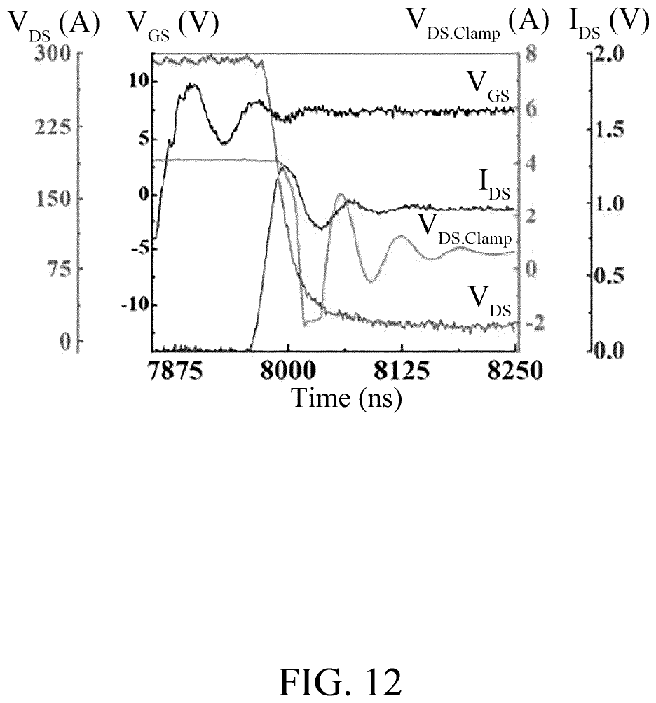

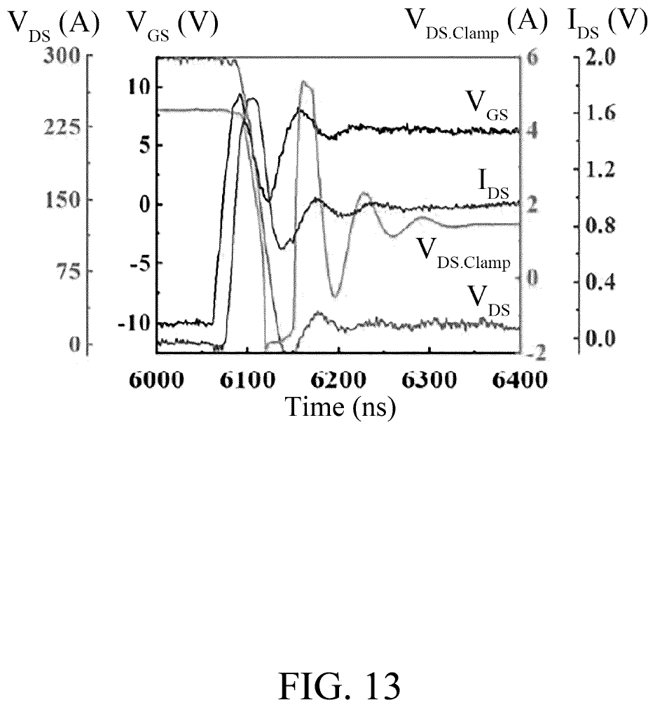

FIGS. 12 and 13 show wave diagrams which are respectively the results from double pulse testing the embodiment samples using the silicon carbide substrate and the silicon substrate. The embodiment sample with the silicon carbide substrate has a switch on time of 71 ns and a switch off time of 52 ns, which corresponds to a total power consumption of 17 μJ and 8.2 μJ, respectively. In comparison, the embodiment sample with the silicon substrate has a switch on time of 103 ns and a switch off time of 191 ns which corresponds to a total power consumption of 26 μJ and 14.9 μJ, respectively.

Therefore, from the above, it is apparent that in comparison to the embodiment sample with the silicon substrate, the embodiment sample with the silicon carbide substrate has a shorter switch on time and switch off time which corresponds to a lower power consumption. Therefore, when the embodiment sample with the silicon carbide substrate has better switching characteristics.

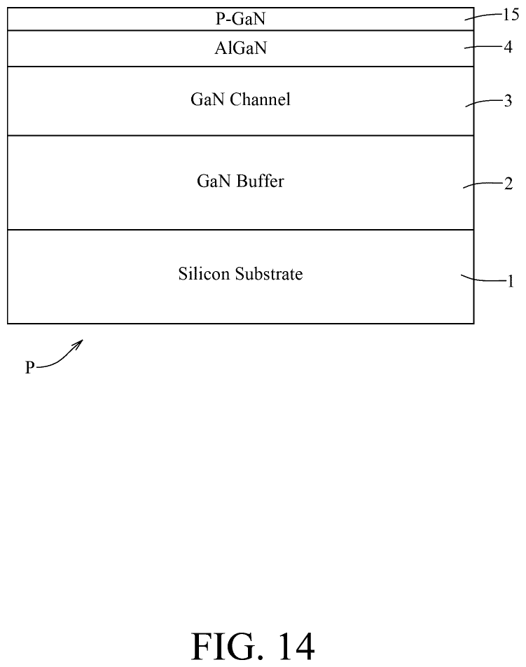

A second embodiment of the present disclosure is a method of making the monolithically integrated GaN cascode of the present disclosure, which is illustrated in FIGS. 14 to 21 as follows. Referring to FIG. 14, firstly, a buffer layer 2, a GaN channel layer 3 an AlGaN layer 4 and a P-GaN cover layer 15 are sequentially formed on a substrate to form a preform structure (P) via epitaxial growth. In an implementation of the method, the buffer layer 2 may be a GaN buffer layer, and may have a total thickness of 5.5 μm. The GaN channel layer 3 may have a thickness of 200 nm. The AlGaN layer 4 may have a thickness of 12 nm, and an aluminum composition of 23% to 25%. Two dimensional electron gas (2DEG) formed in the junction between the AlGaN layer 4 and the GaN channel layer 3 may have a sheet concentration of 5×10¹² cm⁻², and may have an electron mobility of 1350 cm²/V-s. The P-GaN cover layer (P) may have a thickness of 80 nm and may be doped with Mg at a concentration of 2×10¹⁷cm⁻³, and have an electron mobility of 13 cm²/V-s.

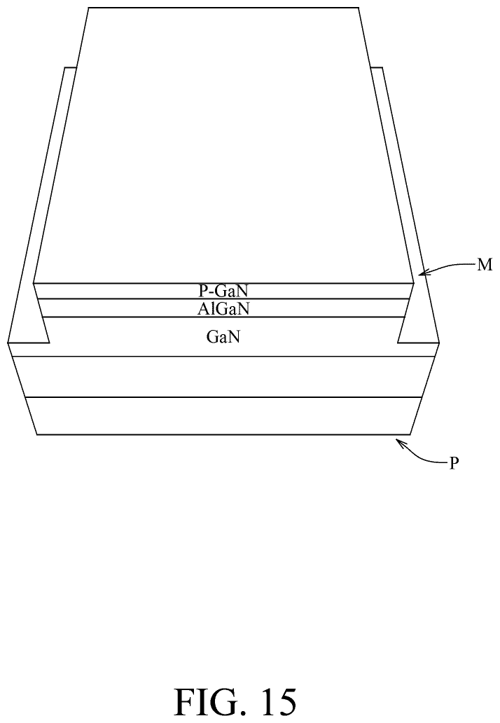

Referring to FIG. 15, the preform structure (P) is etched to form a mesa structure (M) on the preform structure (P), such as by inductively coupled plasma reactive ion etching (ICP-RIE).

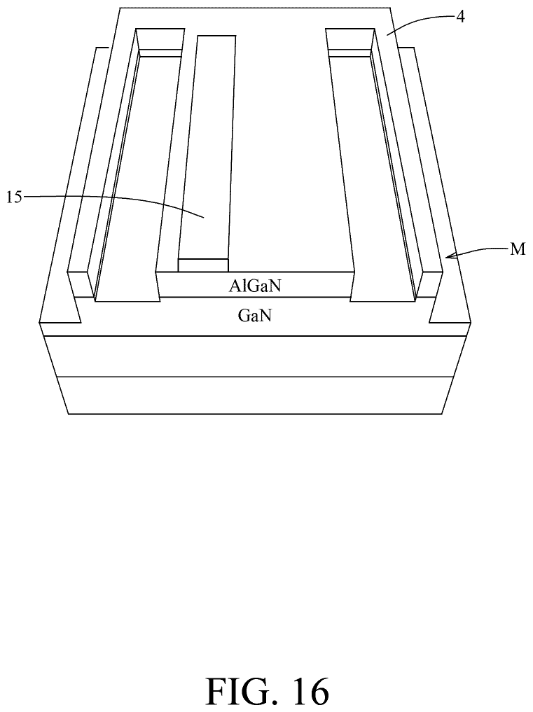

Referring to FIG. 16, the P-GaN cover layer 15 is etched until only a portion of the P-GaN cover layer 15 remains on the AlGaN layer 4, and the AlGaN layer 4 is etched to form two recessed areas respectively in a source region and a drain region of the AlGaN layer; the portion of the P-GaN cover layer is located between the source and drain regions. The portion of the P-GaN cover layer is less than 1 nm in thickness, and the etching of the AlGaN layer 4 is conducted via an ICP-RIE process. Each of the recessed areas of the AlGaN layer 4 has a depth of 20 to 40 mm from a top surface of the AlGaN layer 4. Subsequently, a surface pre-treatment is performed by wet etching and/or dry etching, such as reactive-ion etching (RIE).

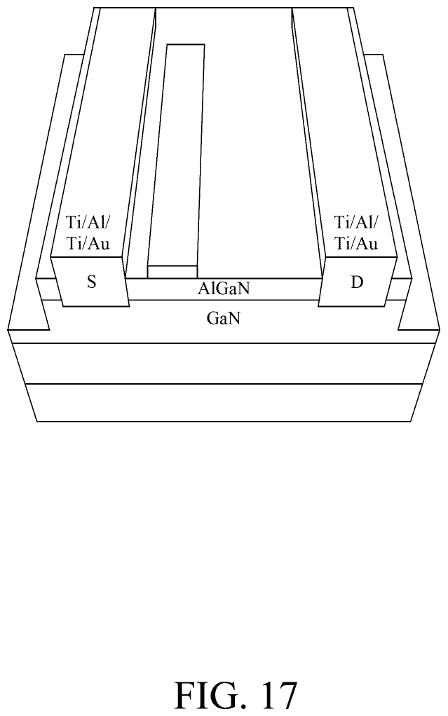

Referring to FIG. 17, an ohmic metal layer is deposited to form a source electrode(S) and a drain electrode (D) on the AlGaN layer 4 by extending the same into each of the recessed areas of the AlGaN layer 4. In this embodiment, the ohmic contact metal layer is a Ti/Al/Ti/Au multilayer having thicknesses of 30/120/40/60 nm. After the ohmic contact metal layer is formed, a rapid thermal annealing (RTA) process is conducted on the ohmic contact metal layer.

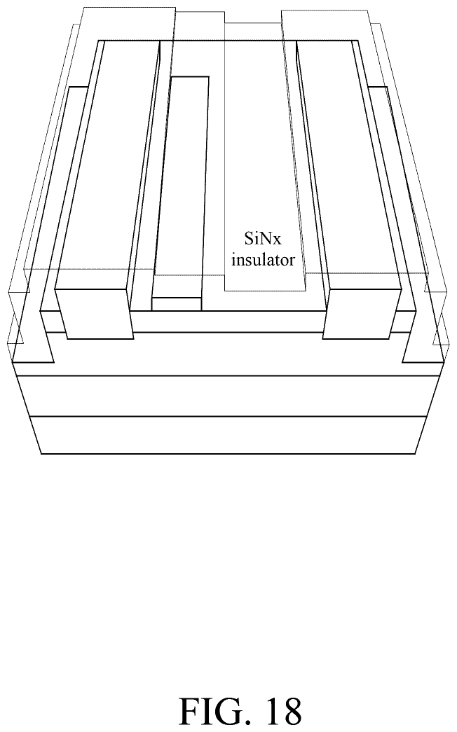

Referring to FIG. 18, a plasma-enhanced chemical vapor deposition (PECVD) process is conducted to form a SiNₓ insulating thin film of 10 nm that covers the source and drain electrodes, the P-type doped GaN cover layer, the AlGaN layer, and the GaN layer.

The SiNₓ insulating thin film is then etched to form via holes (not shown), into which Ni/Au is deposited to form a source electrode pillar, a drain electrode pillar and an E-gate electrode that respectively connect the source electrode, the drain electrode and the P-type doped GaN cover layer as shown in FIG. 19. A D-gate electrode is also formed from Ni/Au on the SiNₓ insulating thin film and is in physical contact with the source electrode pillar; it is located between the E-gate electrode and the drain electrode. The E-gate electrode is in contact with the P-type doped GaN cover layer, whereas the D-gate electrode is in contact with the SiNₓ insulating thin film and thus is a metal-insulator-semiconductor (MIS) gate structure.

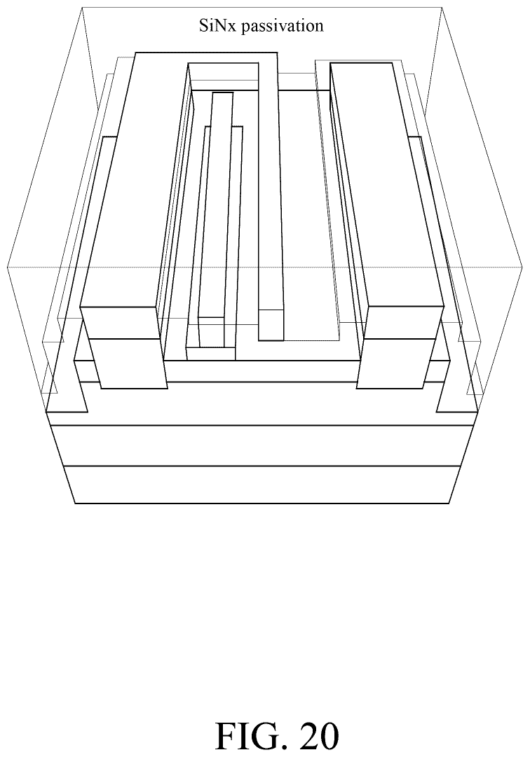

Referring to FIG. 20, a passivation layer is deposited to cover the D-gate electrode and the SiNₓ insulating thin film.

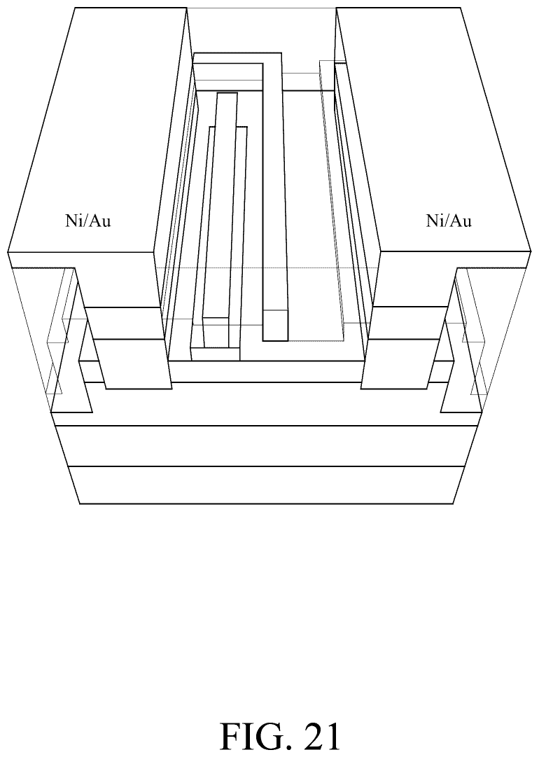

Referring to FIG. 21, Ni/Au metal pads are formed on the passivation layer to respectively connect the source and drain electrode pillars. In summary of the above, in the monolithically integrated GaN cascode according to the present disclosure by disposing the P-type doped GaN layer 71 between the E-gate electrode 72 and the AlGaN layer 4, and by not having the P-type doped GaN layer 71 disposed between the D-gate electrode 8 and the AlGaN layer 4, the junction energy band characteristics between the AlGaN layer 4 and the GaN channel layer 3 may be changed to block the formation of 2DEG which allows the E-gate electrode unit 7 to act as a naturally “off” gate electrode. Therefore, cascoding of a naturally “off” GaN HEMT and a naturally “on” GaN HEMT may be achieved and the monolithically integrated GaN cascode of the present disclosure may thus be formed. In the embodiment, since a fluoride ion implantation area is unnecessary, the crystal structure of the monolithically integrated GaN cascode may be spared from high energy ion bombardment and destruction. This allows the monolithically integrated GaN cascode of the present disclosure to have better electrical characteristics in comparison to conventional GaN HEMTs that must includes a fluoride ion implantation area to form an E-gate electrode.

Furthermore, because the monolithically integrated GaN cascode of the present disclosure is formed from a naturally “on” GaN HEMT cascoded with a naturally “off” GaN HEMT instead of a GaN HEMT and an Si MOSFET, the monolithically integrated GaN cascode according to the present disclosure has advantages such as high heat resistance, decreased packaging complexity, and decreased parasitic capacitance etc.

It should be noted that additional steps can be provided before, during or after the method described hereinbefore, and some of the steps described herein may be replaced by other steps or be eliminated. Similarly, further additional features may be present in the semiconductor structures, and/or features present may be replaced or eliminated in additional embodiments.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A monolithically integrated GaN cascode comprising:
a substrate;
a buffer layer formed on said substrate;
a GaN channel layer formed on said buffer layer;
an AlGaN layer formed on said GaN channel layer;
a source electrode unit formed on said AlGaN layer;
a drain electrode unit formed on said AlGaN layer;
an E-gate electrode unit formed between said source electrode unit and said drain electrode unit on said AlGaN layer, and including a P-type doped GaN layer formed on said AlGaN layer, and an E-gate electrode that is disposed on said P-type doped GaN layer; and
a D-gate electrode unit formed between said source electrode unit and said drain electrode unit on said AlGaN layer, being electrically connected to said source electrode unit, and including a D-gate electrode formed on said AlGaN layer;
wherein said P-type doped GaN layer is disposed between the E-gate electrode and said AlGaN layer, and is not disposed between said D-gate electrode and said AlGaN layer.

2. The monolithically integrated GaN cascode as claimed in claim 1, further comprising a node electrode unit disposed between said E-gate electrode unit and said D-gate electrode unit on said AlGaN layer, and electrically connected to said D-gate electrode unit.

3. The monolithically integrated GaN cascode as claimed in claim 1, further comprising a dielectric layer disposed between said E-gate electrode and said P-type doped GaN layer.

4. The monolithically integrated GaN cascode as claimed in claim 1, further comprising a dielectric layer disposed between said D-gate electrode and said AlGaN layer.

5. The monolithically integrated GaN cascode as claimed in claim 1, further comprising a dielectric layer disposed between said E-gate electrode and said P-type doped GaN layer and between said D-gate electrode and said AlGaN layer.

6. The monolithically integrated GaN cascode as claimed in claim 1, wherein said source electrode unit extends into said GaN channel layer and said AlGaN layer.

7. The monolithically integrated GaN cascode as claimed in claim 1, wherein said drain electrode unit extends into said GaN channel layer and said AlGaN layer.

8. The monolithically integrated GaN cascode as claimed in claim 1 further comprising a source field plate disposed in a spaced apart manner above a side of said D-gate electrode unit that is away from said substrate, and electrically connected to said source electrode.

9. The monolithically integrated GaN cascode as claimed in claim 1, wherein said substrate is a silicon substrate, a silicon carbide substrate, a sapphire substrate or an insulating silicon substrate.

10. The monolithically integrated GaN cascode as claimed in claim 1, wherein said source electrode unit includes a source electrode, a source electrode pillar, and a source electrode pad that are sequentially formed on top of each other on said AlGaN layer.

11. The monolithically integrated GaN cascode as claimed in claim 10, wherein said drain electrode unit includes a drain electrode, a drain electrode pillar, and a drain electrode pad that are sequentially formed on top of each other on said AlGaN layer.

12. The monolithically integrated GaN cascode as claimed in claim 10, wherein each of said source electrode and said drain electrode is formed from a Ti/Al/Ti/Au metal layer.

13. The monolithically integrated GaN cascode as claimed in claim 11, wherein each of said source electrode pillar, said drain electrode pillar, said source electrode pad, and said drain electrode pad is formed from a Ni/Au metal layer.

14. The monolithically integrated GaN cascode as claimed in claim 1, wherein said substrate is a silicon carbide substrate.
